(19) United States
(12) Patent Application Publication
(10) Pub. No.: US 2025/0349568 A1
(43) Pub. Date: Nov. 13, 2025

(54) HEAT TREATMENT METHOD AND HEAT TREATMENT APPARATUS FOR HEATING SUBSTRATE BY LIGHT IRRADIATION

(71) Applicant: SCREEN Holdings Co., Ltd., Kyoto (JP)

(72) Inventors: Oma NAKAJIMA, Kyoto-shi (JP); Katsuichi AKIYOSHI, Kyoto-shi (JP)

(21) Appl. No.: 19/182,383

(22) Filed: Apr. 17, 2025

(30) Foreign Application Priority Data
May 8, 2024 (JP) 2024-075877

(51) Int. Cl. H01L 21/67

(52) U.S. Cl. CPC H01L 21/67115; H01L 21/67248

(57) ABSTRACT

A semiconductor wafer transported into a chamber is preheated by halogen lamps. A comparison is made between a target temperature for the preheating and a measured temperature of the semiconductor wafer which is measured by a radiation thermometer immediately before flash irradiation and in the final stage of the preheating using the halogen lamps. Then, when the measured temperature of the semiconductor wafer is outside an allowable range for the preset target temperature, an alarm is issued, and the treatment of the semiconductor wafer being treated is stopped without the flash irradiation. On the other hand, when the measured temperature of the semiconductor wafer is within the allowable range, the flash irradiation process is performed on the semiconductor wafer.

### BACKGROUND

### Technical Field

The present invention relates to a heat treatment method and a heat treatment apparatus which irradiate a substrate with a flash of light to heat the substrate. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

Japanese Patent Application Laid-Open No. 2018-133424 and U.S. Patent Application Publication No. 2021/0272823 disclose heat treatment apparatuses employing such xenon flash lamps in which desired heat treatment is performed by combining flash lamps disposed on a front surface side of a semiconductor wafer and continuous lighting lamps such as halogen lamps disposed on a back surface side thereof. In such heat treatment apparatuses, the semiconductor wafer is preheated to a certain degree of temperature by the halogen lamps, and the temperature of the front surface of the semiconductor wafer is thereafter increased to a desired treatment temperature by the flash irradiation from the flash lamps. The preheating using the halogen lamps provides a process-related advantage in that the temperature of the semiconductor wafer is increased to a relatively high preheating temperature in a short time,

In the heat treatment techniques disclosed in Japanese Patent Application Laid-Open No. 2018-133424 and U.S. Patent Application Publication No. 2021/0272823, closed-loop control (feedback control) of the output from the halogen lamps is effected so that the wafer temperature reaches a predetermined preheating temperature, while the temperature of the semiconductor wafer is measured by a radiation thermometer. After the temperature of the semiconductor wafer reaches the predetermined preheating temperature, the semiconductor wafer is irradiated with flashes of light from the flash lamps.

Unfortunately, there arise cases in which the temperature of the semiconductor wafer does not reach a target temperature of the closed-loop control during the preheating using the halogen lamps due to various factors such as warpage of the semiconductor wafer, abnormal hardware conditions, and insufficient adjustments of control parameters. If the flash irradiation is performed in this state, desired device properties cannot be obtained in some cases depending on processes. As a result, this gives rise to yield reductions.

In addition, abnormalities in device properties as mentioned above are found by a device performance test which is a process considerably later than the flash heating treatment. Thus, another problem arises in that a considerable amount of time is required before the abnormalities in device properties caused by performing the flash irradiation while the semiconductor wafer temperature does not reach the target temperature of the closed-loop control are recognized.

### SUMMARY

The present invention is intended for a method of irradiating a substrate with a flash of light to heat the substrate.

According to one aspect of the present invention, the method comprises: (a) irradiating a substrate received in a chamber with light from a continuous lighting lamp to preheat the substrate; (b) irradiating a front surface of the substrate with a flash of light from a flash lamp to increase the temperature of the front surface of the substrate, the (b) being performed after the (a); and (c) decreasing the temperature of the substrate in the chamber, the (c) being performed after the (b), wherein a comparison is made between a target temperature for the (a) and a measured temperature of the substrate which is measured by a radiation thermometer, and, when the measured temperature is outside an allowable range for the target temperature, treatment of the substrate is stopped without the irradiation with the flash of light.

Subsequent processes are not performed on the substrate whose measured temperature in the (a) is outside the allowable range for the target temperature. This prevents problems resulting from the flash irradiation process performed on the substrate which has not reached the target temperature.

According to another aspect of the present invention, the method comprises: (a) irradiating a substrate received in a chamber with light from a continuous lighting lamp to preheat the substrate; (b) irradiating a front surface of the substrate with a flash of light from a flash lamp to increase the temperature of the front surface of the substrate, the (b) being performed after the (a); and (c) decreasing the temperature of the substrate in the chamber, the (c) being performed after the (b), wherein a comparison is made between a target output value of the continuous lighting lamp for the (a) and a measured output value being outputted from the continuous lighting lamp, and, when the measured output value is outside an allowable range for the target output value, treatment of the substrate is stopped without the irradiation with the flash of light.

Subsequent processes are not performed on the substrate that is highly likely to have not yet reached the target temperature. This prevents problems resulting from the flash irradiation process performed on the substrate which has not reached the target temperature.

According to another aspect of the present invention, the method comprises: (a) irradiating a substrate received in a chamber with light from a continuous lighting lamp to preheat the substrate; (b) irradiating a front surface of the substrate with a flash of light from a flash lamp to increase the temperature of the front surface of the substrate, the (b) being performed after the (a); and (c) decreasing the temperature of the substrate in the chamber, the (c) being performed after the (b), wherein a comparison is made between a target temperature for the (a) and a measured temperature of the substrate which is measured by a radiation thermometer, and, when the measured temperature is outside an allowable range for the target temperature, the irradiation with the flash of light is placed in a waiting state until the measured temperature falls within the allowable range.

The substrate is irradiated with a flash of light after the temperature of the substrate falls within the allowable range. This prevents problems resulting from the flash irradiation process performed on the substrate which has not reached the target temperature.

Preferably, when a time period during which the irradiation with the flash of light is placed in the waiting state reaches a preset maximum waiting time period, treatment of the substrate is stopped without the irradiation with the flash of light.

A thermal history for the substrate is prevented from becoming excessively large.

Preferably, a time period during which the irradiation with the flash of light is placed in the waiting state is subtracted from a temperature decreasing time period preset as a time period for decrease in temperature of the substrate in the (c).

The time required for the entire substrate treatment is adjusted to a constant.

The present invention is also intended for a heat treatment apparatus for irradiating a substrate with a flash of light to heat the substrate.

According to one aspect of the present invention, the heat treatment apparatus comprises: a chamber for receiving a substrate therein; a continuous lighting lamp for irradiating the substrate received in the chamber with light to preheat the substrate; a flash lamp for irradiating a front surface of the preheated substrate with a flash of light to increase the temperature of the front surface of the substrate; a radiation thermometer for measuring the temperature of the substrate; and a controller that makes a comparison between a target temperature for the preheating and a measured temperature of the substrate which is measured by the radiation thermometer, and, when the measured temperature is outside an allowable range for the target temperature, stops treatment of the substrate without the irradiation with the flash of light.

Subsequent processes are not performed on the substrate whose measured temperature in the preheating is outside the allowable range for the target temperature. This prevents problems resulting from the flash irradiation process performed on the substrate which has not reached the target temperature.

According to another aspect of the present invention, the heat treatment apparatus comprises: a chamber for receiving a substrate therein; a continuous lighting lamp for irradiating the substrate received in the chamber with light to preheat the substrate; a flash lamp for irradiating a front surface of the preheated substrate with a flash of light to increase the temperature of the front surface of the substrate; a radiation thermometer for measuring the temperature of the substrate; and a controller that makes a comparison between a target output value of the continuous lighting lamp for the preheating and a measured output value being outputted from the continuous lighting lamp, and, when the measured output value is outside an allowable range for the target output value, stops treatment of the substrate without the irradiation with the flash of light.

Subsequent processes are not performed on the substrate that is highly likely to have not yet reached the target temperature. This prevents problems resulting from the flash irradiation process performed on the substrate which has not reached the target temperature.

According to another aspect of the present invention, the heat treatment apparatus comprises: a chamber for receiving a substrate therein; a continuous lighting lamp for irradiating the substrate received in the chamber with light to preheat the substrate; a flash lamp for irradiating a front surface of the preheated substrate with a flash of light to increase the temperature of the front surface of the substrate; a radiation thermometer for measuring the temperature of the substrate; and a controller that makes a comparison between a target temperature for the preheating and a measured temperature of the substrate which is measured by the radiation thermometer, and, when the measured temperature is outside an allowable range for the target temperature, places the irradiation with the flash of light in a waiting state until the measured temperature falls within the allowable range.

The substrate is irradiated with a flash of light after the temperature of the substrate falls within the allowable range. This prevents problems resulting from the flash irradiation process performed on the substrate which has not reached the target temperature.

Preferably, when a time period during which the irradiation with the flash of light is placed in the waiting state reaches a preset maximum waiting time period, the controller stops treatment of the substrate without the irradiation with the flash of light.

A thermal history for the substrate is prevented from becoming excessively large.

Preferably, the controller subtracts a time period during which the irradiation with the flash of light is placed in the waiting state from a temperature decreasing time period preset as a time period for decrease in temperature of the substrate after the irradiation with the flash of light.

The time required for the entire substrate treatment is adjusted to a constant.

It is therefore an object of the present invention to prevent problems resulting from a flash irradiation process performed on a substrate which has not reached a target temperature.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus according to the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view showing an arrangement of halogen lamps;

FIG. 8 is a block diagram showing a configuration of a controller;

FIG. 9 is a flow diagram showing a procedure for a treatment operation of a first preferred embodiment in the heat treatment apparatus of FIG. 1;

FIG. 10 is a graph showing changes in temperature of a semiconductor wafer during heat treatment;

FIG. 11 is a flow diagram showing a procedure for the treatment of a second preferred embodiment;

FIG. 12 is a flow diagram showing a procedure for the treatment of a third preferred embodiment;

FIG. 13 is a graph for illustrating a waiting state of flash irradiation; and

FIG. 14 is a graph for illustrating an instance in which the measured temperature of the semiconductor wafer does not fall within an allowable range for a target temperature.

### DESCRIPTION OF THE PREFERRED EMBODIMENTS

Preferred embodiments according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

### First Preferred Embodiment

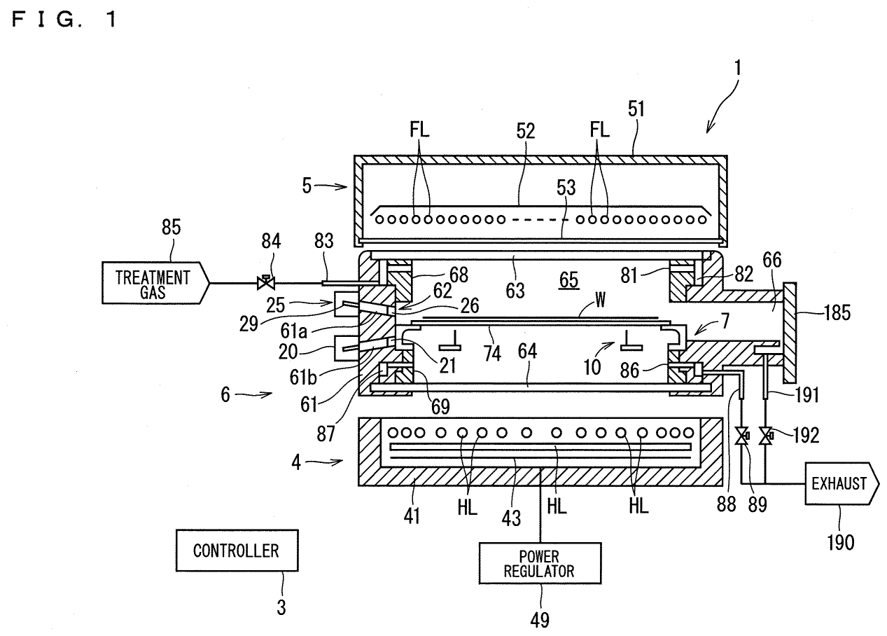

FIG. 1 is a longitudinal sectional view showing a configuration of a heat treatment apparatus 1 according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm (in the present preferred embodiment, 300 mm). It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a and a through hole 61b both bored therein. The through hole 61a is a cylindrical hole for directing infrared light emitted from an upper surface of a semiconductor wafer W held by a susceptor 74 to be described later therethrough to an infrared sensor 29 of an upper radiation thermometer 25. The through hole 61b is a cylindrical hole for directing infrared light emitted from a lower surface of the semiconductor wafer W therethrough to a lower radiation thermometer 20. The through holes 61a and 61b are inclined with respect to a horizontal direction so that the longitudinal axes (axes extending in respective directions in which the through holes 61a and 61b extend through the chamber side portion 61) of the respective through holes 61a and 61b intersect main surfaces of the semiconductor wafer W held by the susceptor 74. A transparent window 26 made of calcium fluoride material transparent to infrared light in a wavelength range measurable with the upper radiation thermometer 25 is mounted to an end portion of the through hole 61a which faces the heat treatment space 65. A transparent window 21 made of barium fluoride material transparent to infrared light in a wavelength range measurable with the lower radiation thermometer 20 is mounted to an end portion of the through hole 61b which faces the heat treatment space 65.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), reactive gases such as hydrogen (H₂) and ammonia (NH₃), and mixtures of these gases (although nitrogen gas is used in the present preferred embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. The treatment gas supply source 85 and the exhaust part 190 may be mechanisms provided in the heat treatment apparatus 1 or be utility systems in a factory in which the heat treatment apparatus 1 is installed.

A gas exhaust pipe 191 for exhausting the gas from the heat treatment space 65 is also connected to a distal end of the transport opening 66. The gas exhaust pipe 191 is connected through a valve 192 to the exhaust part 190. By opening the valve 192, the gas in the chamber 6 is exhausted through the transport opening 66.

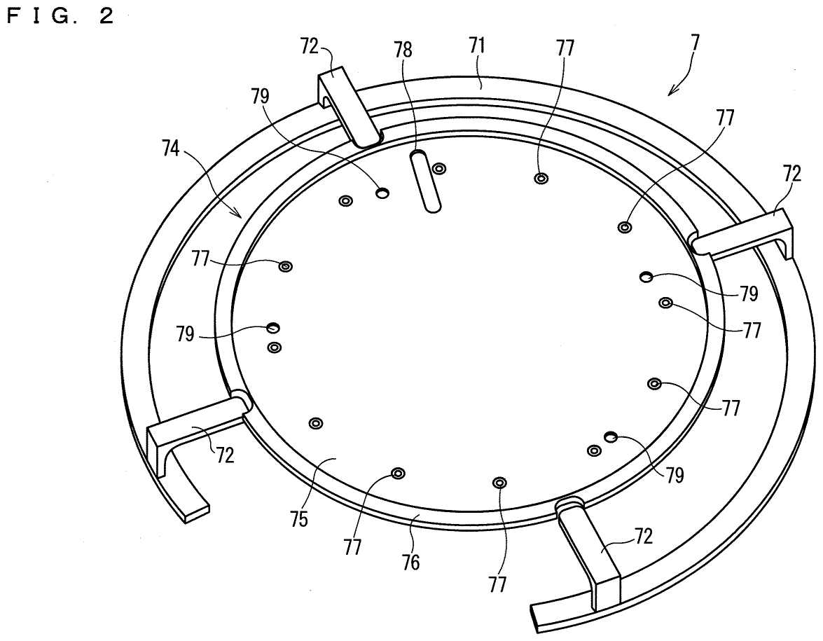

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

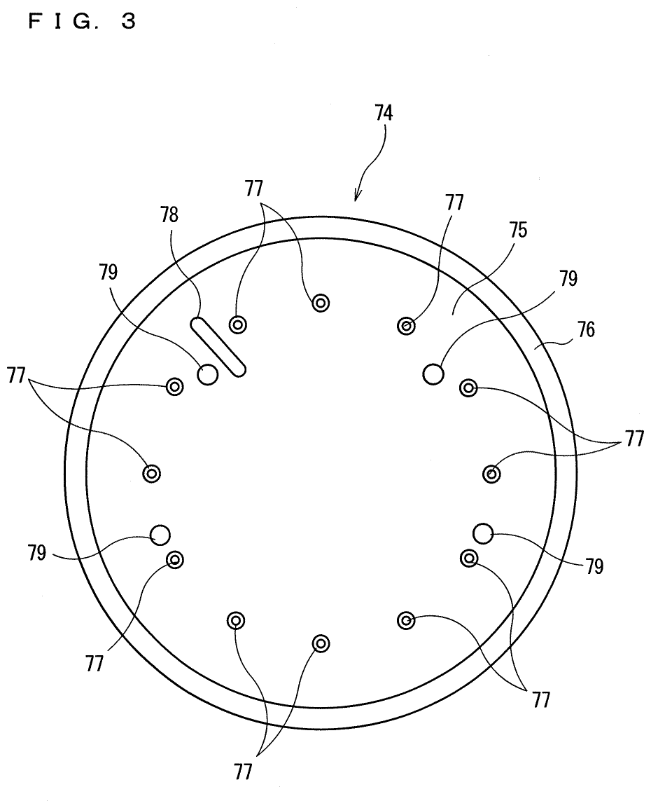

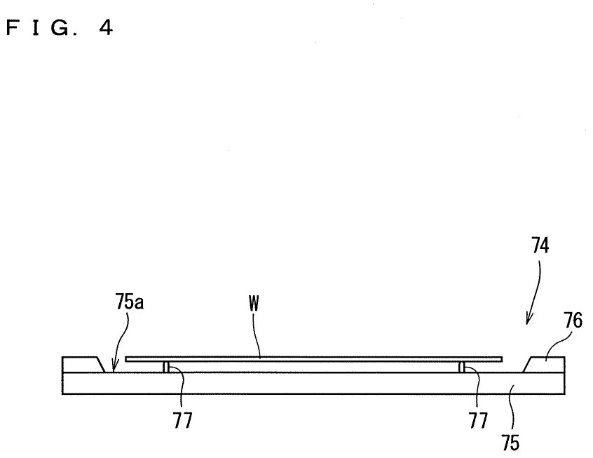

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for the lower radiation thermometer 20 to receive radiation (infrared light) emitted from the lower surface of the semiconductor wafer W. Specifically, the lower radiation thermometer 20 receives the radiation emitted from the lower surface of the semiconductor wafer W through the opening 78 and the transparent window 21 mounted to the through hole 61b in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

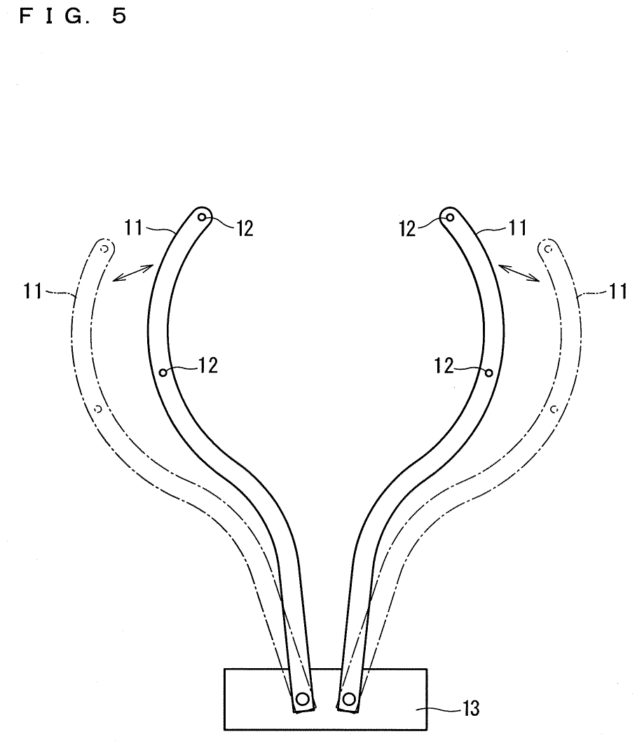

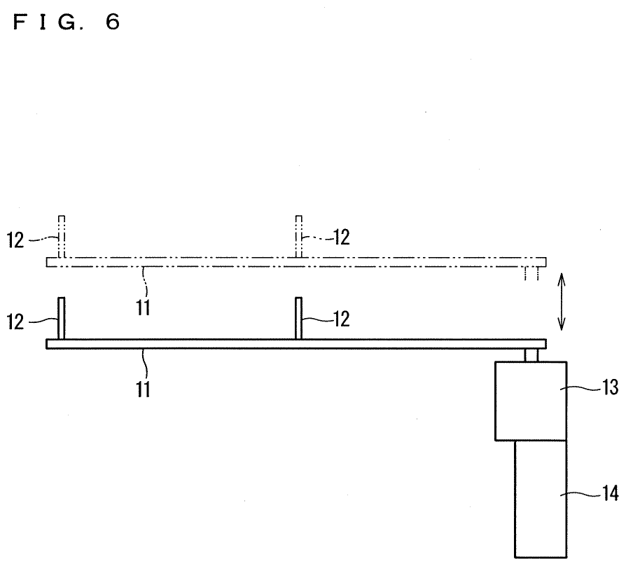

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane. A region in which the flash lamps FL are arranged has a size, as seen in plan view, greater than that of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 is a light irradiator that directs light from under the chamber 6 through the lower chamber window 64 toward the heat treatment space 65 to heat the semiconductor wafer W by means of the halogen lamps HL.

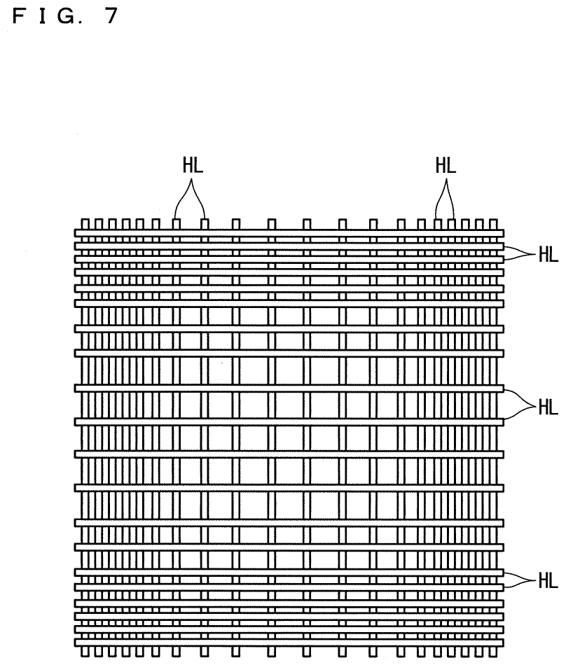

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

As shown in FIG. 1, the heat treatment apparatus 1 includes the upper radiation thermometer 25 and the lower radiation thermometer 20. The upper radiation thermometer 25 is provided obliquely above the semiconductor wafer W held by the susceptor 74, and receives the infrared radiation emitted from the upper surface of the semiconductor wafer W to measure the temperature of the upper surface of the semiconductor wafer W. The infrared sensor 29 of the upper radiation thermometer 25 includes an optical element made of InSb (indium antimonide) so as to be able to respond to rapid changes in temperature of the upper surface of the semiconductor wafer W at the moment of flash irradiation. On the other hand, the lower radiation thermometer 20 is provided obliquely below the semiconductor wafer W held by the susceptor 74, and receives the infrared radiation emitted from the lower surface of the semiconductor wafer W to measure the temperature of the lower surface of the semiconductor wafer W.

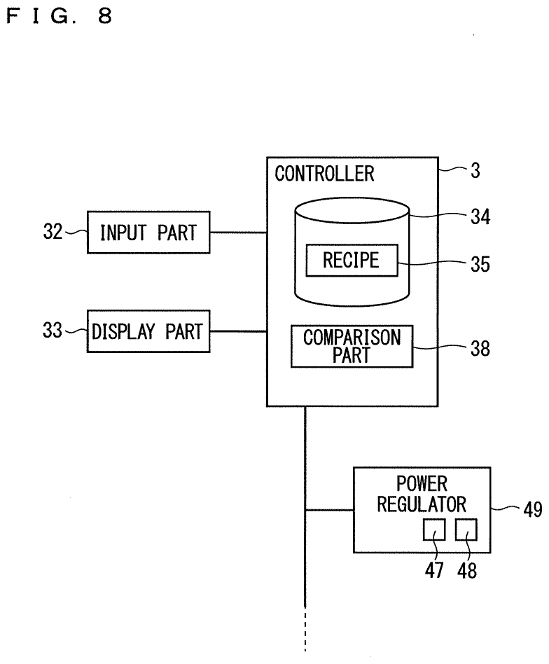

The controller 3 controls the aforementioned various operating mechanisms provided in the heat treatment apparatus 1. FIG. 8 is a block diagram showing a configuration of the controller 3. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part 34 (e.g., a magnetic disk or an SSD) for storing control software, data and the like thereon. The CPU in the controller 3 executes a predetermined processing program, whereby the processes in the heat treatment apparatus 1 proceed.

A treatment recipe 35 which specifies a procedure and conditions for processing or treating the semiconductor wafer W is stored in the storage part 34 of the controller 3. For example, an operator of the heat treatment apparatus 1 enters the treatment recipe 35 via an input part 32 to be described later to store the treatment recipe 35 in the storage part 34, whereby the heat treatment apparatus 1 acquires the treatment recipe 35. Alternatively, the treatment recipe 35 may be transferred via communications from a host computer which manages a plurality of heat treatment apparatuses 1 to the heat treatment apparatus 1 and stored in the storage part 34.

The controller 3 further includes a comparison part 38. The comparison part 38 is a functional processing part implemented by the CPU of the controller 3 executing a predetermined processing program. The details of processing of the comparison part 38 will be described further later.

The controller 3 is electrically connected to an element such as a power regulator 49. The power regulator 49 regulates power to be supplied to the halogen lamps HL provided in the halogen heating part 4. The power regulator 49 includes a voltage monitor 47 and a current monitor 48. The power regulator 49 regulates output power, for example, using thyristor phase control which uses a thyristor. The power regulator 49 monitors the output power by means of the voltage monitor 47 and the current monitor 48. Specifically, the power regulator 49 measures the output power by multiplying the voltage measured by the voltage monitor 47 and the current measured by the current monitor 48 together. The controller 3 provides an instruction value (power instruction value) to the power regulator 49, for example, in accordance with the details of the treatment recipe 35. The power regulator 49 effects power control so that the output power coincides with the instruction value provided thereto while monitoring the output power by means of the voltage monitor 47 and the current monitor 48.

The controller 3 is also connected to a display part 33 and the input part 32. The display part 33 and the input part 32 function as a user interface for the heat treatment apparatus 1. The controller 3 causes a variety of pieces of information to appear on the display part 33. An operator of the heat treatment apparatus 1 may input various commands and parameters from the input part 32 while viewing the information appearing on the display part 33. A keyboard and a mouse, for example, may be used as the input part 32. A liquid crystal display, for example, may be used as the display part 33. In the present preferred embodiment, a liquid crystal touch panel provided on an outer wall of the heat treatment apparatus 1 is used to function as both the display part 33 and the input part 32.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

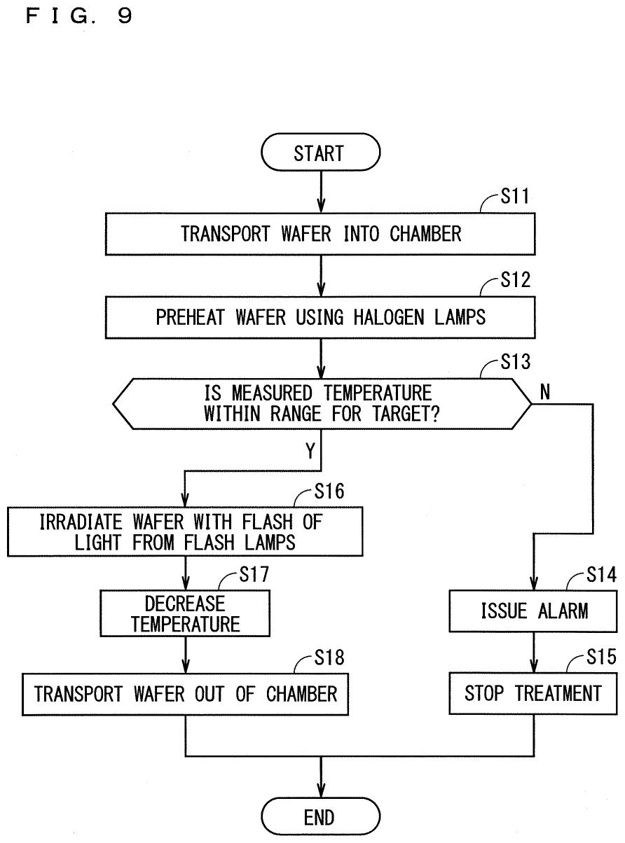

Next, a treatment operation in the heat treatment apparatus 1 will be described. FIG. 9 is a flow diagram showing a procedure for the treatment operation of the first preferred embodiment in the heat treatment apparatus 1. The procedure for the treatment operation which will be described below proceeds under the control of the controller 3 over the operating mechanisms of the heat treatment apparatus 1.

First, the valve 84 for supply of gas is opened, and the valves 89 and 192 for exhaust of gas are opened, so that the supply and exhaust of gas into and out of the chamber 6 start. When the valve 84 is opened, nitrogen gas is supplied through the gas supply opening 81 into the heat treatment space 65. When the valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

The gas within the chamber 6 is exhausted also through the transport opening 66 by opening the valve 192. Further, the exhaust mechanism not shown exhausts an atmosphere near the drivers of the transfer mechanism 10. It should be noted that the nitrogen gas is continuously supplied into the heat treatment space 65 during the heat treatment of a semiconductor wafer W in the heat treatment apparatus 1. The amount of nitrogen gas supplied into the heat treatment space 65 is changed as appropriate in accordance with process steps.

Subsequently, the gate valve 185 is opened to open the transport opening 66. A transport robot outside the heat treatment apparatus 1 transports the semiconductor wafer W to be treated through the transport opening 66 into the heat treatment space 65 of the chamber 6 (Step S11). At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface thereof that is patterned is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, the 40 halogen lamps HL in the halogen heating part 4 turn on simultaneously to start preheating (or assist-heating) (Step S12). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

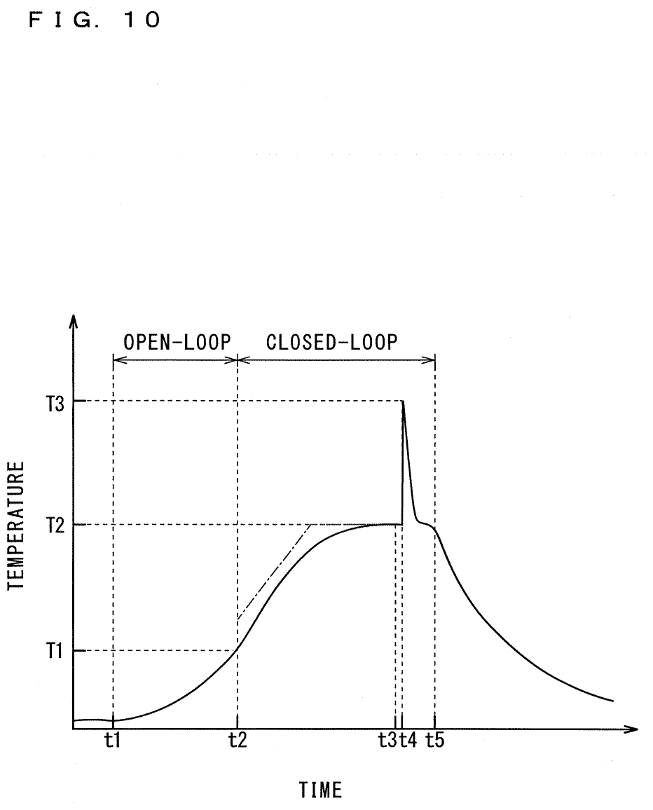

FIG. 10 is a graph showing changes in temperature of the semiconductor wafer W during the heat treatment. At time t1, the halogen lamps HL turn on to start the preheating of the semiconductor wafer W. The output control of the halogen lamps HL during the preheating has two stages: a first stage in which open-loop control is effected; and a second stage in which closed-loop control is effected.

The lower radiation thermometer 20 which monitors the temperature of the semiconductor wafer W during the preheating is unable to accurately measure the temperature of the semiconductor wafer W when the temperature of the semiconductor wafer W is relatively low. In other words, the closed-loop control cannot be effected because it is difficult to measure the temperature of an object to be controlled. For this reason, when the temperature of the semiconductor wafer W is relatively low in the early period of the preheating, the controller 3 effects the open-loop control to control the output from the halogen lamps HL. Specifically, between times t1 and t2 in FIG. 10, the controller 3 continuously provides a predetermined instruction value to the power regulator 49, and the power regulator 49 supplies power to the halogen lamps HL in accordance with the instruction value. The open-loop control is continued until the temperature of the semiconductor wafer W reaches a switching temperature T1. The switching temperature T1 is a temperature at which the temperature of the semiconductor wafer W becomes accurately measurable by the lower radiation thermometer 20, and is between 450° C. and 500° C., for example.

At the time t2 when the temperature of the semiconductor wafer W reaches the switching temperature T1, the control is switched from the open-loop control to the closed-loop control. In other words, the controller 3 effects the closed-loop control to control the output from the halogen lamps HL after the time t2. When the closed-loop control is being effected, the temperature of the semiconductor wafer W is measured by the lower radiation thermometer 20. Specifically, the lower radiation thermometer 20 receives infrared radiation emitted from the lower surface of the semiconductor wafer W held by the susceptor 74 through the opening 78 and passing through the transparent window 21 to measure the temperature of the semiconductor wafer W which is on the increase. The measured temperature of the semiconductor wafer W is transmitted to the controller 3.

The controller 3 makes a comparison between the temperature of the semiconductor wafer W measured by the lower radiation thermometer 20 and a target value indicated by dash-dot lines in FIG. 10 to provide an instruction value calculated in accordance with the difference therebetween to the power regulator 49. The power regulator 49 regulates the power to be supplied to the halogen lamps HL in accordance with the instruction value provided thereto. In other words, the controller 3 effects the closed-loop control (feedback control) of the output from the halogen lamps HL so that the temperature of the semiconductor wafer W coincides with the target value, based on the value measured by the lower radiation thermometer 20. In this manner, the lower radiation thermometer 20 is a radiation thermometer for controlling the temperature of the semiconductor wafer W in the closed-loop control during the preheating.

As indicated by the dash-dot lines in FIG. 10, the target value of the closed-loop control changes in such a manner as to increase at a predetermined rate to a predetermined preheating temperature T2 and to thereafter be remain constant (at the preheating temperature T2) for a while. In other words, the target temperature (the preheating temperature T2) for the preheating is also the target value of the closed-loop control. Thus, if the output from the halogen lamps HL is properly controlled so that the temperature of the semiconductor wafer W coincides with the target value, the temperature of the semiconductor wafer W will reach and be maintained at the preheating temperature T2.

At time t3 immediately before the flash irradiation from the flash lamps FL in a soak phase (a temperature maintenance step) where the semiconductor wafer W is preheated using the halogen lamps HL, the comparison part 38 of the controller 3 makes a comparison between the target temperature (the preheating temperature T2) for the preheating and the measured temperature of the semiconductor wafer W which is measured by the lower radiation thermometer 20. Specifically. the comparison part 38 judges whether the measured temperature of the semiconductor wafer W which is measured by the lower radiation thermometer 20 falls within an allowable range for the target temperature or not (Step S13).

Prior to the start of the treatment of the semiconductor wafer W to be treated, for example, an operator of the heat treatment apparatus 1 may enter such an allowable range from the input part 32 and be previously set in the treatment recipe 35. In other words, the input part 32 accepts a setting input of the allowable range. For example, the allowable range is set to 5° C. for a target temperature (preheating temperature T2) of 800° C. In this case, the comparison part 38 judges whether the measured temperature of the semiconductor wafer W falls within the range of 795° to 805° C. or not. The wider the allowable range is set, the more lenient the judgment in Step S13 is.

If the measured temperature of the semiconductor wafer W which is measured by the lower radiation thermometer 20 falls outside the allowable range for the target temperature as a result of the comparison in Step S13, the procedure proceeds to Step S14 in which the controller 3 issues an alarm. Specifically, for example, the controller 3 may display a warning message on the display part 33 or emit a warning sound. Examples of conceivable factors which cause the measured temperature of the semiconductor wafer W to fall outside the allowable range include warpage of the semiconductor wafer W, abnormal hardware conditions, and insufficient adjustments of control parameters in the closed-loop control.

Subsequently, the controller 3 stops the treatment of the semiconductor wafer W in the heat treatment apparatus 1 (Step S15). In other words, the controller 3 stops the treatment without irradiating the semiconductor wafer W being treated with flashes of light.

On the other hand, if the measured temperature of the semiconductor wafer W which is measured by the lower radiation thermometer 20 falls within the allowable range for the target temperature, the procedure proceeds from Step S13 to Step S16 in which the front surface of the semiconductor wafer W is irradiated with flashes of light from the flash lamps FL. The flashes of light emitted from the flash lamps FL at time t4 are transmitted through the lamp light radiation window 53 and the upper chamber window 63, and reach the front surface of the semiconductor wafer W. The time period from the time t3 at which the judgment is made by the comparison between the target temperature and the measured temperature to the time t4 at which the flash irradiation is performed is less than one second.

A flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. Such an extremely short and intense flash of light enters the interior of the chamber 6 and impinges upon the front surface of the semiconductor wafer W. This causes the front surface temperature of the semiconductor wafer W to momentarily increase to a treatment temperature T3 and to thereafter decrease rapidly.

At time t5 when a predetermined time period has elapsed since the completion of the flash heating using the flash irradiation, the halogen lamps HL turn off. This causes the temperature of the semiconductor wafer W to decrease also from the preheating temperature T2 (Step S17). The lower radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the lower radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 out of the chamber 6. Thus, the heating treatment of the semiconductor wafer W is completed (Step S18).

In the first preferred embodiment, the comparison part 38 compares the target temperature (the preheating temperature T2) for the preheating with the measured temperature of the semiconductor wafer W which is measured by the lower radiation thermometer 20 immediately before the flash irradiation and in the final stage of the preheating using the halogen lamps HL. Then, if the measured temperature of the semiconductor wafer W is outside the allowable range for the preset target temperature, the controller 3 issues an alarm, and stops the treatment of the semiconductor wafer W being treated without the flash irradiation. In other words, an interlock is provided in the case where the measured temperature of the semiconductor wafer W does not satisfy the conditions.

If the measured temperature of the semiconductor wafer W is outside the allowable range for the target temperature, the treatment is stopped without the irradiation of the semiconductor wafer W with flashes of light. For this reason, no subsequent processes are performed on the semiconductor wafer W, and no devices are manufactured. This prevents problems resulting from the flash irradiation process performed on the semiconductor wafer W which has not reached the target temperature for the preheating.

In addition, treatment failure is detected and the treatment is stopped immediately before the flash irradiation. This allows the detection of abnormalities in an early period.

Further, the flash irradiation is performed after the checking of the temperature of the semiconductor wafer W falling within the allowable range for the target temperature. This achieves stable treatment results.

### Second Preferred Embodiment

Next, a second preferred embodiment of the present invention will be described. The configuration of the heat treatment apparatus in the second preferred embodiment is the same as that of the heat treatment apparatus 1 in the first preferred embodiment. The procedure for the treatment of the semiconductor wafer W in the second preferred embodiment is substantially the same as that in the first preferred embodiment. Although the judgment is made by the comparison between the measured temperature of the semiconductor wafer W and the target value in the first preferred embodiment, a judgment is made by a comparison between an output value of the halogen lamps HL and a target value in the second preferred embodiment.

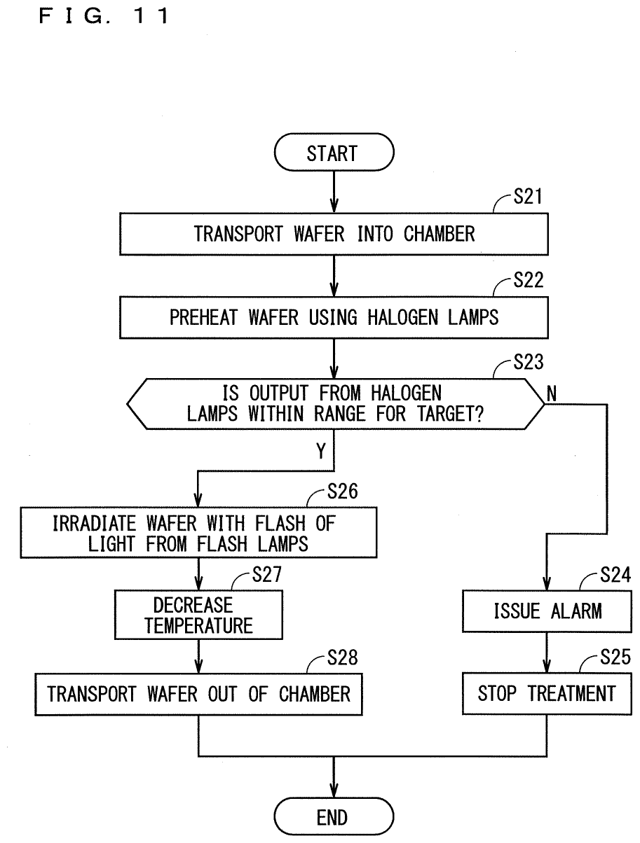

FIG. 11 is a flow diagram showing the procedure for the treatment of the second preferred embodiment. The processes in Steps S21 and S22 of the second preferred embodiment are the same as the processes in Steps S11 and S12 of the first preferred embodiment. Specifically, the semiconductor wafer W is transported into the chamber 6 and held by the susceptor 74, following which the preheating using the halogen lamps HL starts. As in the first preferred embodiment, the output control of the halogen lamps HL during the preheating has two stages: the first stage in which the open-loop control is effected; and the second stage in which the closed-loop control is effected.

In the second preferred embodiment, at the time t3 immediately before the flash irradiation, the comparison part 38 of the controller 3 makes a comparison between a target output value of the halogen lamps HL for the preheating and a measured output value being actually outputted from the halogen lamps HL. The measured output value being actually outputted from the halogen lamps HL is determined from measurement results of the voltage monitor 47 and the current monitor 48 which are provided in the power regulator 49. The output value of the halogen lamps HL may be determined as a ratio with respect to a maximum output. In Step S23, the comparison part 38 judges whether the measured output value of the halogen lamps HL falls within an allowable range for the target output value or not.

Prior to the start of the treatment of the semiconductor wafer W to be treated, for example, an operator of the heat treatment apparatus 1 may enter the target output value of the halogen lamps HL for the preheating and the allowable range from the input part 32 and be previously set in the treatment recipe 35. For example, the operator of the heat treatment apparatus 1 enters 30% as the target output value and 5% as the allowable range. In this case, the comparison part 38 judges whether the measured output value of the halogen lamps HL at the time t3 falls within the range of 25% to 35% or not.

If the measured output value of the halogen lamps HL falls outside the allowable range for the target output value as a result of the comparison in Step S23, the procedure proceeds to Step S24 in which the controller 3 issues an alarm. Subsequently, the controller 3 stops the treatment without irradiating the semiconductor wafer W being treated with flashes of light (Step S25).

On the other hand, if the measured output value of the halogen lamps HL falls within the allowable range for the target output value, the procedure proceeds from Step S23 to Step S26 in which the front surface of the semiconductor wafer W is irradiated with flashes of light from the flash lamps FL. Extremely short and intense flashes of light impinge upon the semiconductor wafer W. This causes the front surface temperature of the semiconductor wafer W to momentarily increase to the treatment temperature T3 and to thereafter decrease rapidly.

At the time t5 when a predetermined time period has elapsed since the completion of the flash heating using the flash irradiation, the halogen lamps HL turn off. This causes the temperature of the semiconductor wafer W to decrease also from the preheating temperature T2 (Step S27). After the temperature of the semiconductor wafer W is decreased to a predetermined temperature or below, the heat-treated semiconductor wafer W is transported out of the chamber 6 (Step S28). Thus, the treatment of the semiconductor wafer W is completed.

In the second preferred embodiment, the comparison part 38 compares the target output value of the halogen lamps HL for the preheating with the measured output value being actually outputted from the halogen lamps HL immediately before the flash irradiation and in the final stage of the preheating using the halogen lamps HL. Then, if the measured output value of the halogen lamps HL is outside the allowable range for the target output value, the controller 3 issues an alarm, and stops the treatment of the semiconductor wafer W being treated without the flash irradiation. In other words, an interlock is provided in the case where the measured output value of the halogen lamps HL does not satisfy the conditions.

If the measured output value being actually outputted from the halogen lamps HL is outside the allowable range for the target output value, there is a high probability that the temperature of the semiconductor wafer W has not yet reached the target temperature (the preheating temperature T2). In such a case, the treatment is stopped without the irradiation of the semiconductor wafer W being treated with flashes of light. For this reason, no subsequent processes are performed on the semiconductor wafer W, and no devices are manufactured. This prevents problems resulting from the flash irradiation process performed on the semiconductor wafer W which has not reached the target temperature for the preheating.

As in the first preferred embodiment, treatment failure is detected and the treatment is stopped immediately before the flash irradiation. This allows the detection of abnormalities in an early period.

Further, the flash irradiation is performed after the checking of the measured output value of the halogen lamps HL falling within the allowable range for the target output value. This achieves stable treatment results.

### Third Preferred Embodiment

Next, a third preferred embodiment of the present invention will be described. The configuration of the heat treatment apparatus in the third preferred embodiment is the same as that of the heat treatment apparatus 1 in the first preferred embodiment. The procedure for the treatment of the semiconductor wafer W in the third preferred embodiment is substantially the same as that in the first preferred embodiment. Although the treatment is stopped if the measured temperature of the semiconductor wafer W falls outside the allowable range for the target temperature in the first preferred embodiment, a waiting state continues until the measured temperature falls within the allowable range in the third preferred embodiment.

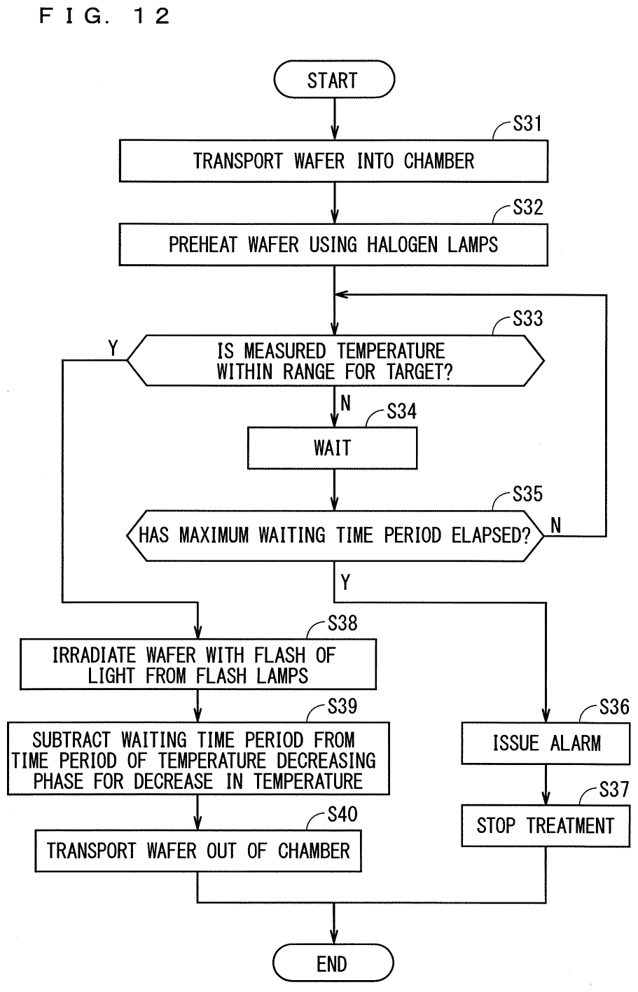

FIG. 12 is a flow diagram showing the procedure for the treatment of the third preferred embodiment. The processes in Steps S31 and S32 of the third preferred embodiment are the same as the processes in Steps S11 and S12 of the first preferred embodiment. Specifically, the semiconductor wafer W is transported into the chamber 6 and held by the susceptor 74, following which the preheating using the halogen lamps HL starts. As in the first preferred embodiment, the output control of the halogen lamps HL during the preheating has two stages: the first stage in which the open-loop control is effected; and the second stage in which the closed-loop control is effected.

In the third preferred embodiment, at the time t3 immediately before the flash irradiation, the comparison part 38 of the controller 3 makes a comparison between the target temperature (the preheating temperature T2) for the preheating and the measured temperature of the semiconductor wafer W which is measured by the lower radiation thermometer 20. Specifically. the comparison part 38 judges whether the measured temperature of the semiconductor wafer W which is measured by the lower radiation thermometer 20 falls within the allowable range for the target temperature or not (Step S33). As in the first preferred embodiment, an operator of the heat treatment apparatus 1 may previously enter such an allowable range from the input part 32 and be set in the treatment recipe 35.

If the measured temperature of the semiconductor wafer W which is measured by the lower radiation thermometer 20 falls outside the allowable range for the target temperature as a result of the comparison in Step S33, the procedure proceeds to Step S34 in which the controller 3 places the flash irradiation from the flash lamps FL into the waiting state and causes the halogen lamps HL to continue to heat the semiconductor wafer W. This further increases the temperature of the semiconductor wafer W.

Subsequently, the controller 3 judges whether the elapsed time since the start of the waiting state of the flash irradiation has reached a maximum waiting time period or not (Step S35). The operator of the heat treatment apparatus 1 may also previously enter such a maximum waiting time period from the input part 32. If the elapsed time since the start of the waiting state of the flash irradiation has not reached the maximum waiting time period, the procedure returns to Step S33, and the processes in Steps S33 to S35 are repeated. In other words, the flash irradiation is placed in the waiting state until the measured temperature of the semiconductor wafer W which is measured by the lower radiation thermometer 20 falls within the allowable range for the target temperature.

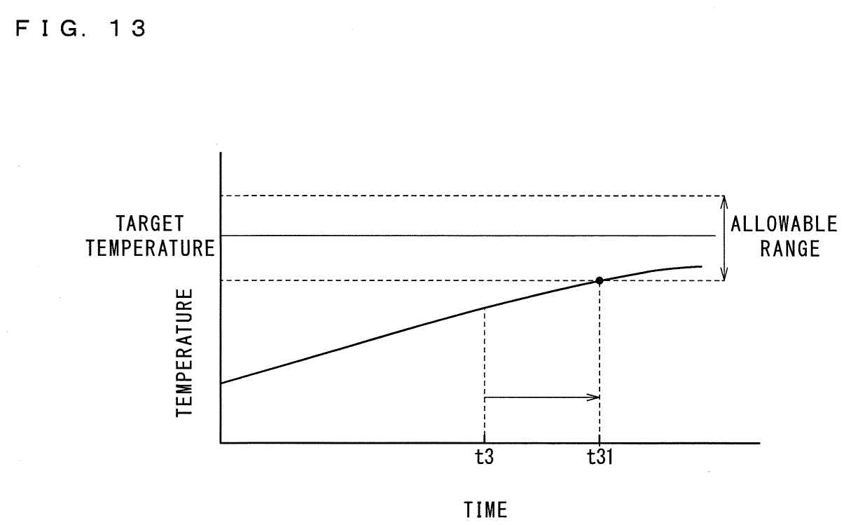

FIG. 13 is a graph for illustrating the waiting state of the flash irradiation. In FIG. 13, dotted lines indicate the allowable range for the target temperature. At the time t3, the measured temperature of the semiconductor wafer W which is measured by the lower radiation thermometer 20 has not yet reached the allowable range for the target temperature. For this reason, the controller 3 places the flash irradiation into the waiting state, and causes the halogen lamps HL to continue to heat the semiconductor wafer W. This causes the temperature of the semiconductor wafer W to further increase and to approach the target temperature.

Thereafter, the processes in Steps S33 to S35 are repeated. In the course of time, at time t31, the measured temperature of the semiconductor wafer W which is measured by the lower radiation thermometer 20 falls within the allowable range for the target temperature. In other words, the controller 3 places the flash irradiation in the waiting state from the time t3 to the time t31 at which the measured temperature of the semiconductor wafer W falls within the allowable range for the target temperature.

On the other hand, if the elapsed time since the start of the waiting state of the flash irradiation reaches the maximum waiting time period without the measured temperature of the semiconductor wafer W falling within the allowable range for the target temperature, the procedure proceeds from Step S35 to Step S36 in which the controller 3 issues an alarm. Subsequently, the controller 3 stops the treatment without irradiating the semiconductor wafer W being treated with flashes of light (Step S37). The maximum waiting time period is, for example, approximately 10 seconds.

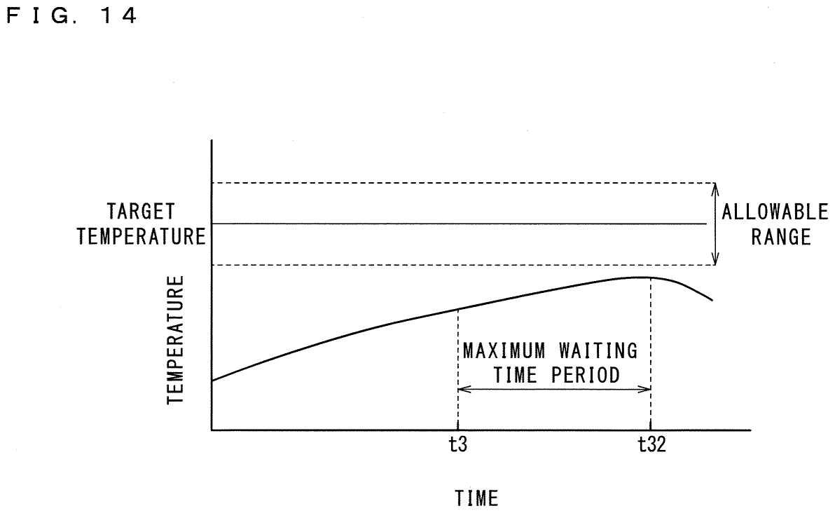

FIG. 14 is a graph for illustrating an instance in which the measured temperature of the semiconductor wafer W does not fall within the allowable range for the target temperature. In FIG. 14, dotted lines indicate the allowable range for the target temperature, as in FIG. 13. At the time t3, the measured temperature of the semiconductor wafer W which is measured by the lower radiation thermometer 20 has not yet reached the allowable range for the target temperature. For this reason, the controller 3 places the flash irradiation into the waiting state, and causes the halogen lamps HL to continue to heat the semiconductor wafer W. This causes the temperature of the semiconductor wafer W to further increase and to approach the target temperature.

Thereafter, the processes in Steps S33 to S35 are repeated, but if the measured temperature of the semiconductor wafer W does not fall within the allowable range for the target temperature even at time t32 when the maximum waiting time period has elapsed since the start of the waiting state of the flash irradiation, the controller 3 issues an alarm. Then, the controller 3 stops the treatment of the semiconductor wafer W being treated without the flash irradiation. In other words, if the elapsed time since the time t3 when the waiting state of the flash irradiation starts reaches the maximum waiting time period without the measured temperature of the semiconductor wafer W falling within the allowable range for the target temperature, the controller 3 issues an alarm and stops the treatment of the semiconductor wafer W being treated.

On the other hand, if the measured temperature of the semiconductor wafer W falls within the allowable range for the target temperature before the maximum waiting time period has elapsed since the start of the waiting state of the flash irradiation, the procedure proceeds from Step S33 to Step S38 in which the front surface of the semiconductor wafer W is irradiated with flashes of light from the flash lamps FL. Extremely short and intense flashes of light impinge upon the semiconductor wafer W. This causes the front surface temperature of the semiconductor wafer W to momentarily increase to the treatment temperature T3 and to thereafter decrease rapidly.

After a predetermined time period has elapsed since the completion of the flash heating using the flash irradiation, the halogen lamps HL turn off. This causes the temperature of the semiconductor wafer W to decrease also from the preheating temperature T2. For the decrease in temperature, the aforementioned waiting time period during which the flash irradiation is placed in the waiting state is subtracted from a temperature decreasing time period which is preset as the time period for the decrease in temperature of the semiconductor wafer W in the third preferred embodiment (Step S39).

In general, a temperature decreasing phase to which a sufficient amount of time (e.g., 30 seconds or more) is assigned is set in the treatment recipe 35. The controller 3 performs time management by subtracting the time period during which the flash irradiation is placed in the waiting state from the time period of the temperature decreasing phase having a sufficient time allowance. As a result, the time period initially set in the treatment recipe 35 for the decrease in temperature of the semiconductor wafer W becomes shorter by the amount of time during which the flash irradiation is placed in the waiting state.

Thereafter, at the time when the time period of the temperature decreasing phase obtained by subtracting the time period during which the flash irradiation is placed in the waiting state has elapsed, the heat-treated semiconductor wafer W is transported out of the chamber 6. Thus, the treatment of the semiconductor wafer W is completed (Step S40).

In the third preferred embodiment, the comparison part 38 compares the target temperature (the preheating temperature T2) for the preheating with the measured temperature of the semiconductor wafer W which is measured by the lower radiation thermometer 20 immediately before the flash irradiation and in the final stage of the preheating using the halogen lamps HL. Then, if the measured temperature of the semiconductor wafer W is outside the allowable range for the preset target temperature, the flash irradiation is placed in the waiting state until the measured temperature of the semiconductor wafer W falls within the allowable range.

If the measured temperature of the semiconductor wafer W is outside the allowable range for the target temperature, the flash irradiation is placed in the waiting state until the temperature of the semiconductor wafer W falls within the allowable range. For this reason, the semiconductor wafer W at a temperature falling outside the allowable range is prevented from being irradiated with flashes of light. This prevents problems resulting from the flash irradiation process performed on the semiconductor wafer W which has not reached the target temperature for the preheating.

Further, the flash irradiation is performed after the temperature of the semiconductor wafer W falls within the allowable range for the target temperature. This achieves stable treatment results.

In the third preferred embodiment, on the other hand, the treatment of the semiconductor wafer W is stopped without the flash irradiation if the temperature of the semiconductor wafer W does not fall within the aforementioned allowable range even when the time period during which the flash irradiation is placed in the waiting state reaches the preset maximum waiting time period. The heating using the halogen lamps HL continues even while the flash irradiation is in the waiting state. As a result, if the waiting time period becomes excessively long, the thermal history (thermal budget) for the semiconductor wafer W will become too large. For this reason, as in the third preferred embodiment, the maximum waiting time period is previously set, and the treatment is stopped when the time period during which the flash irradiation is placed in the waiting state reaches the maximum waiting time period, whereby the thermal history for the semiconductor wafer W is prevented from becoming too large.

Further, the time period during which the flash irradiation is placed in the waiting state is subtracted from the temperature decreasing time period which is preset as the time period for the decrease in temperature of the semiconductor wafer W after the flash irradiation in the third preferred embodiment. This allows the treatment time period for one semiconductor wafer W in the heat treatment apparatus 1 to be adjusted to a constant time period set in the treatment recipe 35. The time period previously set for the decrease in temperature of the semiconductor wafer W becomes shorter by the amount of time during which the flash irradiation is placed in the waiting state. However, the time period for the decrease in temperature of the semiconductor wafer W has a sufficient time allowance. Thus, the slight shortening of the time period for the decrease in temperature of the semiconductor wafer W presents no problem.

### Modifications

While the preferred embodiments according to the present invention have been described hereinabove, various modifications of the present invention in addition to those described above may be made without departing from the scope and spirit of the invention. For example, the judgment is made by the comparison between the measured temperature of the semiconductor wafer W and the target value in the first preferred embodiment, and the judgment is made by the comparison between the output value of the halogen lamps HL and the target value in the second preferred embodiment. However, both of the judgments may be made. In this case, the treatment of the semiconductor wafer W may be stopped without the flash irradiation if the measured temperature of the semiconductor wafer W is outside the allowable range for the target temperature and if the measured output value of the halogen lamps HL is outside the allowable range for the target output value. Alternatively, the treatment of the semiconductor wafer W may be stopped without the flash irradiation if the measured temperature of the semiconductor wafer W is outside the allowable range for the target temperature or if the measured output value of the halogen lamps HL is outside the allowable range for the target output value.

For example, which one of the judgment by the comparison between the measured temperature of the semiconductor wafer W and the target value and the judgment by the comparison between the output value of the halogen lamps HL and the target value is to be made may be set appropriately in the treatment recipe 35. Only one of the judgments, both of the judgments, or neither of the judgments may be made. If only one of the judgments is to be made, it is preferable to make the judgment by the comparison between the measured temperature of the semiconductor wafer W and the target value.

In addition, the variable time period for the open-loop control as the first stage of the preheating of the semiconductor wafer W may be absorbed by the temperature decreasing time period preset as the time period for the decrease in temperature of the semiconductor wafer W. Specifically, the time period for the decrease in temperature of the semiconductor wafer W is decreased when the time period for the open-loop control is long, and the time period for the decrease in temperature of the semiconductor wafer W is increased when the time period for the open-loop control is short. This allows the treatment time period of the semiconductor wafer W to be made more constant. The time period for the closed-loop control as the second stage of the preheating is constant because the closed-loop control is the control effected so that the temperature of the semiconductor wafer W coincides with the given target value.

Although the 30 flash lamps FL are provided in the flash heating part 5 according to the aforementioned preferred embodiments, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

In the aforementioned preferred embodiments, the filament-type halogen lamps HL are used as continuous lighting lamps that emit light continuously for not less than one second to perform the preheating of the semiconductor wafer W. The present invention, however, is not limited to this. In place of the halogen lamps HL, discharge type arc lamps (e.g., xenon arc lamps) or LED lamps may be used as the continuous lighting lamps to perform the preheating.

While the invention has been shown and described in detail, the foregoing description is in all aspects illustrative and not restrictive. It is therefore understood that numerous modifications and variations can be devised without departing from the scope of the invention.

What is claimed is:

1. A method of irradiating a substrate with a flash of light to heat the substrate, said method comprising:
(a) irradiating a substrate received in a chamber with light from a continuous lighting lamp to preheat said substrate;
(b) irradiating a front surface of said substrate with a flash of light from a flash lamp to increase the temperature of the front surface of said substrate, said (b) being performed after said (a); and
(c) decreasing the temperature of said substrate in said chamber, said (c) being performed after said (b),
wherein a comparison is made between a target temperature for said (a) and a measured temperature of said substrate which is measured by a radiation thermometer, and, when said measured temperature is outside an allowable range for said target temperature, treatment of said substrate is stopped without the irradiation with said flash of light.

2. The method according to claim 1,
wherein said (a) includes effecting closed-loop control of an output from said continuous lighting lamp, and
wherein said target temperature is a target value of said closed-loop control.

3. The method according to claim 1, further comprising
(d) setting said allowable range before the treatment of said substrate starts.

4. A method of irradiating a substrate with a flash of light to heat the substrate, said method comprising:
(a) irradiating a substrate received in a chamber with light from a continuous lighting lamp to preheat said substrate;
(b) irradiating a front surface of said substrate with a flash of light from a flash lamp to increase the temperature of the front surface of said substrate, said (b) being performed after said (a); and
(c) decreasing the temperature of said substrate in said chamber, said (c) being performed after said (b),
wherein a comparison is made between a target output value of said continuous lighting lamp for said (a) and a measured output value being outputted from said continuous lighting lamp, and, when said measured output value is outside an allowable range for said target output value, treatment of said substrate is stopped without the irradiation with said flash of light.

5. The method according to claim 4,
wherein a comparison is made between a target temperature for said (a) and a measured temperature of said substrate which is measured by a radiation thermometer, and, when said measured temperature is outside an allowable range for said target temperature, treatment of said substrate is stopped without the irradiation with said flash of light.

6. The method according to claim 4, further comprising
(d) setting said allowable range for said target output value before the treatment of said substrate starts.

7. A method of irradiating a substrate with a flash of light to heat the substrate, said method comprising:
(a) irradiating a substrate received in a chamber with light from a continuous lighting lamp to preheat said substrate;
(b) irradiating a front surface of said substrate with a flash of light from a flash lamp to increase the temperature of the front surface of said substrate, said (b) being performed after said (a); and
(c) decreasing the temperature of said substrate in said chamber, said (c) being performed after said (b),
wherein a comparison is made between a target temperature for said (a) and a measured temperature of said substrate which is measured by a radiation thermometer, and, when said measured temperature is outside an allowable range for said target temperature, the irradiation with said flash of light is placed in a waiting state until said measured temperature falls within said allowable range.

8. The method according to claim 7,
wherein, when a time period during which the irradiation with said flash of light is placed in the waiting state reaches a preset maximum waiting time period, treatment of said substrate is stopped without the irradiation with said flash of light.

9. The method according to claim 7,
wherein a time period during which the irradiation with said flash of light is placed in the waiting state is subtracted from a temperature decreasing time period preset as a time period for decrease in temperature of said substrate in said (c).

10. The method according to claim 7, further comprising
(d) setting said allowable range before the treatment of said substrate starts.

11. A heat treatment apparatus for irradiating a substrate with a flash of light to heat the substrate, comprising:
a chamber for receiving a substrate therein;
a continuous lighting lamp for irradiating said substrate received in said chamber with light to preheat said substrate;
a flash lamp for irradiating a front surface of the preheated substrate with a flash of light to increase the temperature of the front surface of said substrate;
a radiation thermometer for measuring the temperature of said substrate; and
a controller that makes a comparison between a target temperature for said preheating and a measured temperature of said substrate which is measured by said radiation thermometer, and, when said measured temperature is outside an allowable range for said target temperature, stops treatment of said substrate without the irradiation with said flash of light.

12. The heat treatment apparatus according to claim 11,
wherein closed-loop control of an output from said continuous lighting lamp is effected during said preheating, and
wherein said target temperature is a target value of said closed-loop control.

13. The heat treatment apparatus according to claim 11, further comprising
an input part for accepting a setting input of said allowable range before the treatment of said substrate starts.

14. A heat treatment apparatus for irradiating a substrate with a flash of light to heat the substrate, comprising:
a chamber for receiving a substrate therein;
a continuous lighting lamp for irradiating said substrate received in said chamber with light to preheat said substrate;
a flash lamp for irradiating a front surface of the preheated substrate with a flash of light to increase the temperature of the front surface of said substrate;
a radiation thermometer for measuring the temperature of said substrate; and
a controller that makes a comparison between a target output value of said continuous lighting lamp for said preheating and a measured output value being outputted from said continuous lighting lamp, and, when said measured output value is outside an allowable range for said target output value, stops treatment of said substrate without the irradiation with said flash of light.

15. The heat treatment apparatus according to claim 14,
wherein said controller makes a comparison between a target temperature for said preheating and a measured temperature of said substrate which is measured by said radiation thermometer, and, when said measured temperature is outside an allowable range for said target temperature, stops treatment of said substrate without the irradiation with said flash of light.

16. The heat treatment apparatus according to claim 14, further comprising
an input part for accepting a setting input of said allowable range for said target output value before the treatment of said substrate starts.

17. A heat treatment apparatus for irradiating a substrate with a flash of light to heat the substrate, comprising:
a chamber for receiving a substrate therein;
a continuous lighting lamp for irradiating said substrate received in said chamber with light to preheat said substrate;
a flash lamp for irradiating a front surface of the preheated substrate with a flash of light to increase the temperature of the front surface of said substrate;
a radiation thermometer for measuring the temperature of said substrate; and
a controller that makes a comparison between a target temperature for said preheating and a measured temperature of said substrate which is measured by said radiation thermometer, and, when said measured temperature is outside an allowable range for said target temperature, places the irradiation with said flash of light in a waiting state until said measured temperature falls within said allowable range.

18. The heat treatment apparatus according to claim 17,
wherein, when a time period during which the irradiation with said flash of light is placed in the waiting state reaches a preset maximum waiting time period, said controller stops treatment of said substrate without the irradiation with said flash of light.

19. The heat treatment apparatus according to claim 17,
wherein said controller subtracts a time period during which the irradiation with said flash of light is placed in the waiting state from a temperature decreasing time period preset as a time period for decrease in temperature of said substrate after the irradiation with said flash of light.

20. The heat treatment apparatus according to claim 17, further comprising
an input part for accepting a setting input of said allowable range before the treatment of said substrate starts.
